(19) United States
(12) Patent Application Publication
(10) Pub. No.: US 2016/0079101 A1
(43) Pub. Date: Mar. 17, 2016

(54) SUBSTRATE PROCESSING APPARATUS, METHOD OF MANUFACTURING SEMICONDUCTOR DEVICE AND NON-TRANSITORY COMPUTER-READABLE RECORDING MEDIUM

(71) Applicant: HITACHI KOKUSAI ELECTRIC INC., Tokyo (JP)

(72) Inventors: Hidehiro YANAI, Toyama-shi (JP); Yoshihiko YANAGISAWA, Toyama-shi (JP); Yasutoshi TSUBOTA, Toyama-shi (JP)

(73) Assignee: HITACHI KOKUSAI ELECTRIC INC., Tokyo (JP)

(21) Appl. No.: 14/848,634

(22) Filed: Sep. 9, 2015

(30) Foreign Application Priority Data
Sep. 17, 2014 (JP) 2014-188824

(51) Int. Cl. H01L 21/67; H01L 21/3065

(52) U.S. Cl. CPC H01L 21/67248; H01L 21/3065; H01L 21/67069

(57) ABSTRACT

The present invention provides a structure and a technique through which a reaction heat generated in a substrate process can be absorbed in a low temperature range and a temperature of a substrate support (susceptor) can remain at a predetermined temperature or less. There is provided a substrate processing apparatus including: a substrate support including a heater and a cooling channel; a heater power supply; a thermal detector; a coolant supply unit; a controller configured to control the heater power supply and the coolant supply unit to: supply a first power to the heater without a substrate placed on the substrate support while supplying the coolant to the cooling channel; and supply a second power to the heater with the substrate placed on the substrate support while supplying the coolant to the cooling channel.

### CROSS-REFERENCE TO RELATED PATENT APPLICATION

This non-provisional U.S. patent application claims priority under 35 U.S.C. §119 of Japanese Patent Application No. 2014-188824, filed on Sep. 17, 2014, the entire contents of which are hereby incorporated by reference.

### BACKGROUND OF THE INVENTION

1. Field of the Invention

The present invention relates to a substrate processing apparatus configured to process a substrate, a method of manufacturing a semiconductor device and a non-transitory computer-readable recording medium.

2. Description of the Related Art

It is known that a significant amount of reaction heat is generated when a substrate (wafer) is processed with a gas having an etching characteristic of removing silicon or a silicon oxide at a high speed. It is known that, when a film formed directly above an entire wafer is removed using, for example, IF₇ (iodine heptafluoride) during a reaction process of IF₇+Si [symbol] SiF₄+IF₅, a reaction heat up to about 1,000 W is generated. Also, it is known that removing silicon using IF₇ is highly selective, but the fact that selectivity decreases as a temperature of the wafer increases is also found. When the temperature of the wafer is greater than about 70° C. to 90° C., since selectivity when silicon is removed significantly decreases, it is necessary to maintain the temperature of the wafer to be lower than this temperature range. Meanwhile, there are many cases in which silicon to be removed is doped with impurities. Exemplary impurities include phosphorus (P), boron (B) and carbon (C). It is known that, in order to remove residues of silicon doped with impurities or remove residues in a pattern, a somewhat higher temperature (30° C. to 50° C.) is better.

### RELATED DOCUMENTS

### Patent Literature

1. Japanese Laid-open Patent Application No. 2012-94652

2. Japanese Laid-open Patent Application No. 2010-212371

However, in a substrate support (susceptor) of a general substrate processing apparatus, only a heating device or only a cooling device is generally installed. Also, even when the heating device and the cooling device are provided, cooling (heating) is generally performed to a constant temperature or less (more). There is no device configured to sensitively monitor and adjust a temperature in a low temperature range near a room temperature as described above.

### SUMMARY OF THE INVENTION

The present invention provides a structure and a method through which a reaction heat generated due to a substrate process can be absorbed in a low temperature range and a temperature of a susceptor can remain at a predetermined temperature or less.

According to an aspect of the present invention, there is provided a substrate processing apparatus including: a substrate support including a heater and a cooling channel; a heater power supply configured to supply power to the heater; a thermal detector comprising a thermal detecting part disposed lower than an upper surface of the substrate support and higher than lower ends of the heater and the cooling channel; a coolant supply unit configured to supply a coolant to the cooling channel; a controller configured to control the heater power supply and the coolant supply unit to: supply a first power to the heater without a substrate placed on the substrate support while supplying the coolant to the cooling channel; and supply a second power to the heater with the substrate placed on the substrate support while supplying the coolant to the cooling channel.

### BRIEF DESCRIPTION OF THE DRAWINGS

FIG. 1 is a cross sectional view of a main part of a single wafer type substrate processing apparatus according to an embodiment of the present invention when a substrate is processed.

FIG. 2 is a schematic cross sectional view of a substrate processing apparatus according to an embodiment of the present invention and is a diagram illustrating a state in which a susceptor is positioned at a transfer position at which a substrate transfer process can be performed.

FIG. 3 shows an exemplary structure of a controller according to an embodiment of the present invention.

FIG. 4 shows an exemplary flow of a substrate processing process according to an embodiment of the present invention.

FIG. 5 is a vertical cross sectional view of a susceptor according to an embodiment of the present invention.

FIG. 6 is a top cross sectional view taken along A-A′ and B-B′ in FIG. 5.

FIG. 7 is a vertical cross sectional view of a terminal part of a heater (from a direction D) according to an embodiment of the present invention.

FIG. 8 is a vertical cross sectional view of a terminal part of a cooling pipe (from a direction E) according to an embodiment of the present invention.

FIG. 9 is an image of a heat path in a susceptor according to an embodiment of the present invention.

FIG. 10 shows the graph of an exemplary operation according to an embodiment of the present invention.

### DETAILED DESCRIPTION OF THE PREFERRED EMBODIMENTS

Next, exemplary embodiments of the present invention will be described.

The inventors have found a structure and a technique through which a reaction heat generated due to silicon etching can be absorbed in a low temperature range near a room temperature and a substrate support (susceptor) can maintain a constant temperature. Specifically, in a temperature range of about 30° C. to 70° C. in which an influence such as an ambient temperature is easily delivered and control thereof is difficult, sensitive control of a temperature of the substrate is possible. In process performance, selectivity of silicon etching can increase, a temperature of the substrate can be set to a temperature range in which added residues can decrease. Therefore, it is possible to contribute to performance differentiation of silicon etching.

### First Embodiment

Hereinafter, exemplary embodiments of the present invention will be described in further detail with reference to the drawings.

(1) Configuration of Substrate Processing Apparatus

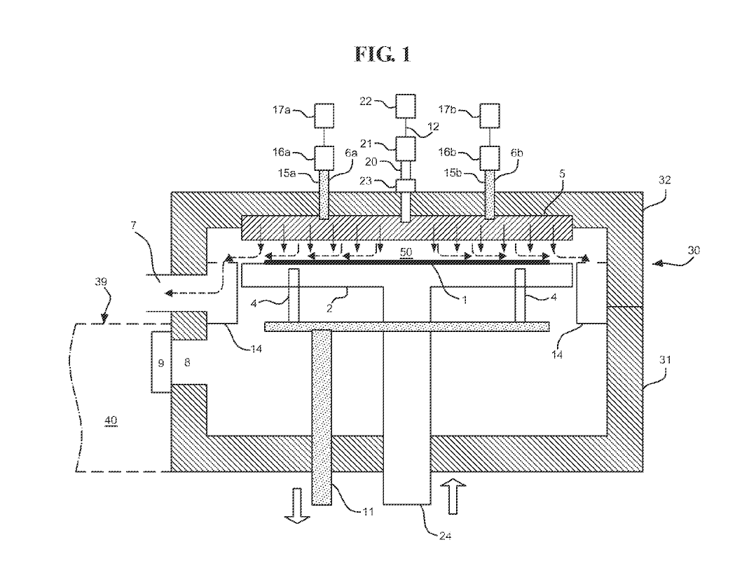

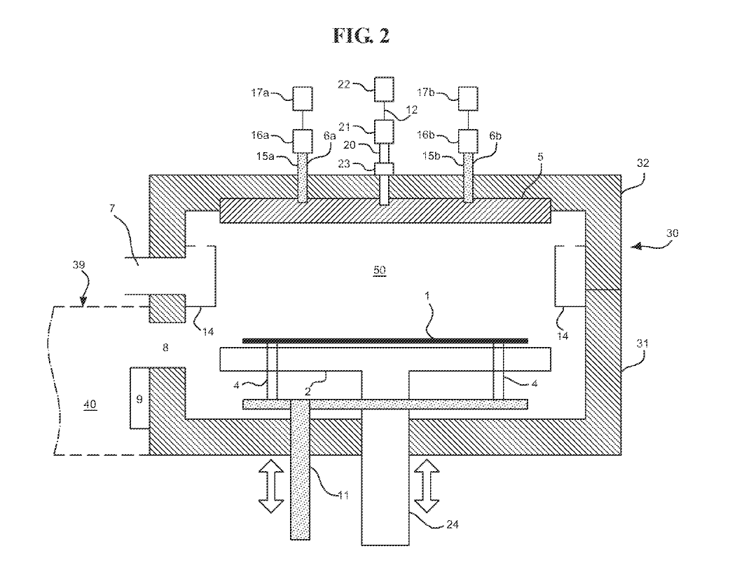

FIG. 1 is a cross sectional view of a main part of a single wafer type substrate processing apparatus (hereinafter simply referred to as a “substrate processing apparatus”) configured to perform a method of manufacturing a semiconductor device when a process is performed. FIG. 2 is a schematic cross sectional view of the substrate processing apparatus, and is a diagram illustrating a state in which a susceptor is lowered and positioned at a transfer position at which a substrate transfer process can be performed.

In FIGS. 1 and 2, the substrate processing apparatus includes a processing container 30 configured to process a substrate 1 and a substrate transfer container 39 that is adjacent to the processing container 30 and transfers the substrate 1 into the processing container 30.

The processing container 30 includes a container main body 31 whose upper part is opened and a lid 32 closing an upper opening of the container main body 31, and a processing chamber 50 having an enclosed structure is formed therein. Also, the processing chamber 50 may be formed in a space surrounded by the lid 32 and a susceptor 2.

In the lid 32, a shower head 5, processing gas supply lines 6a and 6b and an inert gas supply line 12 are installed. The shower head 5 is installed to face the substrate 1 in the processing chamber 50 and is installed to supply a processing gas into the processing chamber 50. The shower head 5 is installed on an inner upper surface of the lid 32, and includes a gas dispersion plate (not illustrated) including a plurality of gas holes and configured to disperse a gas in a shower form and a mixing chamber (not illustrated) configured to mix a plurality of gases.

The gas supply lines 6a and 6b are connected to the shower head 5 and are configured to supply a processing gas into the substrate processing chamber 50 through the shower head 5. Specifically, a gas supply line 6 includes gas supply pipes 15a and 15b that are connected to the shower head 5 and communicate with the mixing chamber and gas flow rate controllers (mass flow controllers: MFCs) 16a and 16b installed at the gas supply pipes 15a and 15b, and can supply a desired gas type into the substrate processing chamber 50 at a desired gas flow rate and a desired gas ratio. Also, gas supply sources 17a and 17b may be included in the gas supply line (gas supply unit).

In the container main body 31, an exhaust port 7, a transfer port 8 and the susceptor 2 in which a heater unit and a cooling channel are embedded are installed. The exhaust port 7 is installed in an upper part of the container main body 31, communicates with a circular path 14 formed in an upper inner circumference of the container main body 31, and exhausts an inside of the substrate processing chamber 50 through the circular path 14. Also, the transfer port 8 is installed at a side lower than the exhaust port 7 of the container main body 31, loads the substrate 1 such as a silicon wafer, before processing, from a substrate transfer chamber 40 formed in the transfer container 39 to the substrate processing chamber 50 in the processing container 30 through the transfer port 8, or unloads the processed substrate 1 from the substrate processing chamber 50 to the substrate transfer chamber 40. Also, an on-off valve 9 that can be switched and configured to isolate an atmosphere in the substrate transfer chamber 40 and the substrate processing chamber 50 is installed at the transfer port 8 of the container main body 31.

The above-described susceptor 2 is installed to be vertically movable in the substrate processing chamber 50 of the processing container 30, and the substrate 1 is maintained on a surface of the susceptor 2. The substrate 1 is heated by the heater unit (not illustrated) or cooled by the cooling channel through the susceptor 2. Also, the susceptor 2 will be described in detail below.

A plurality of support pins 4 stand on a substrate support pin up and down mechanism 11. These support pins 4 can penetrate through the susceptor 2, and are retractable from a surface of the susceptor 2 according to lifting of the susceptor 2 and the substrate support pin up and down mechanism 11.

In the substrate processing apparatus, when the susceptor 2 is lowered and positioned at a position at which a transfer process can be performed [FIG. 2, hereinafter this position is referred to as a “transfer position A”], the plurality of support pins 4 protrude from the susceptor 2, the substrate 1 can be supported on the plurality of support pins 4, and the substrate 1 can be transferred or unloaded between the substrate processing chamber 50 and the substrate transfer chamber 40 through the transfer port 8. Also, in the substrate processing apparatus, when the susceptor 2 is raised, passed an intermediate position above the transfer position A and positioned at a position at which a processing process can be performed [FIG. 1, hereinafter this position is referred to as a “substrate processing position B] , the support pin 4 is not associated with the substrate 1, and the substrate 1 is placed on the susceptor 2.

The susceptor 2 has a support shaft 24 that is connected to a lifting mechanism, and is installed to be vertically movable in the substrate processing chamber 50. The lifting mechanism may adjust a position [such as the transfer position A and the substrate processing position B] of the susceptor 2 in the substrate processing chamber 50 in a vertical direction in multiple steps in processes such as a substrate loading process, a substrate processing process and a substrate unloading process.

Also, the susceptor 2 is rotatable. That is, the tubular support shaft 24 is rotatable according to a rotating mechanism (not illustrated), and the susceptor 2 in which the heater (heating element) and the cooling channel are embedded is rotatable about the support shaft 24. While the substrate 1 is maintained, the susceptor 2 is rotatable at any rate.

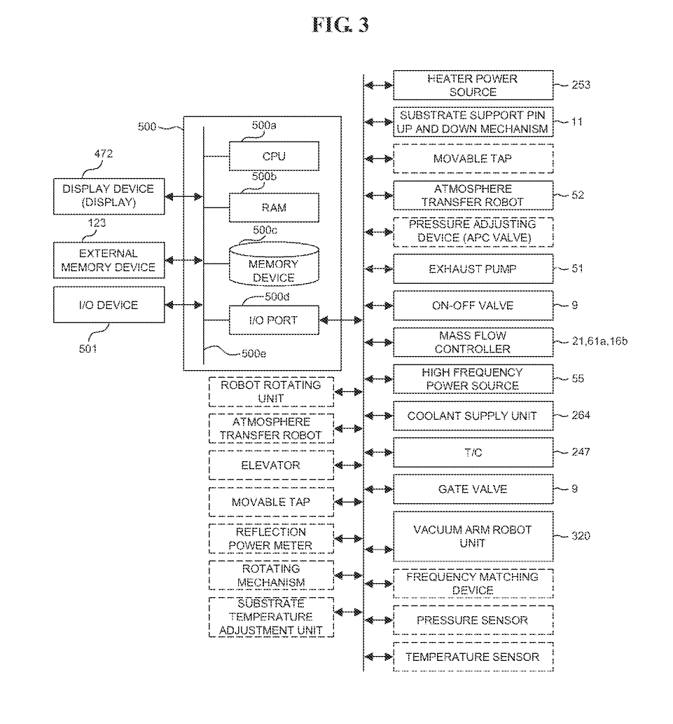

Although a control device configured to control respective components such as the lifting mechanism, the rotating mechanism, a resistance heater and the MFCs 21 and 16 (16a and, 16b) is not illustrated, an exemplary structure of a controller serving as the control device is illustrated in FIG. 3.

In order to remove a thin film on the substrate in the substrate processing apparatus described above, the substrate 1 is loaded into the processing chamber 50 in the transfer process, a processing gas (etching gas) and a non-processing gas (for example, an inert gas) are supplied to the substrate 1 loaded into the processing chamber 50 through the shower head 5 to process the substrate 1 in the processing process, and the substrate 1 is unloaded from an inside of the processing chamber 50 in the unloading process.

[Controller]

As illustrated in FIG. 3, a controller 500 serving as a controller (control device) is configured as a computer that includes a central processing unit (CPU) 500a, a random access memory (RAM) 500b, a memory device 500c and an I/O port 500d. The RAM 500b, the memory device 500c and the I/O port 500d are configured to exchange data with the CPU 500a through an internal bus 500e. An I/O device 501 configured as, for example, a touch panel, is connected to the controller 500. The controller 500 controls respective components described above in order to perform the substrate processing process to be described below.

The memory device 500c is configured as, for example, a flash memory and a hard disk drive (HDD). A control program controlling operations of the substrate processing apparatus, a process recipe describing sequences or conditions of substrate processing to be described below and the like are readably stored in the memory device 500c. Also, the process recipe, which is a combination of sequences, causes the controller 500 to execute each sequence in the substrate processing process to be described below in order to obtain a predetermined result, and functions as a program. Hereinafter, such a process recipe, a control program and the like are collectively simply called a “program.” Also, when the term “program” is used in this specification, it may refer to either or both of the process recipe and the control program. Also, the RAM 500b is configured as a memory area (work area) in which a program, data and the like read by the CPU 500a are temporarily stored.

The I/O port 500d is connected to the substrate support pin up and down mechanism 11, the heater unit, a cooling unit, an APC valve, the MFCs 21, 16a and 16b, the on-off valve 9, an exhaust pump, an atmosphere transfer robot, a gate valve, a vacuum arm robot unit and the like. Also, when an exciting unit is installed, the I/O port 500d may be connected to a high frequency power source, a movable tap, a reflection power meter and a frequency matching device.

The CPU 500a reads and executes the control program from the memory device 500c, and reads the process recipe from the memory device 500c according to an input of a manipulating command from the I/O device 501. To comply with the content of the read process recipe, the CPU 500a controls a vertical movement of the support pin 4 by the substrate support pin up and down mechanism 11, a heating and cooling operation of the wafer 1 by the heater and the cooling unit, a pressure adjustment operation by the APC valve, a flow rate adjustment operation of a processing gas by the mass flow controllers 21, 16a and 16b and the on-off valve 9 and the like. Also, it is needless to say that the CPU 500a may control a configuration of, for example, a robot rotating unit or an atmosphere transfer robot indicated by a broken line in FIG. 3.

Also, the controller 500 is not limited to being configured as a dedicated computer, but may be configured as a general-purpose computer. For example, the controller 500 according to the present embodiment may be configured by preparing an external memory device 123 [for example, a magnetic tape, a magnetic disk such as a flexible disk or a hard disk, an optical disc such as a CD or a DVD, a magneto-optical disc such as an MO, and a semiconductor memory such as a USB memory (USB flash drive) or a memory card] recording the above program, and then installing the program in the general-purpose computer using the external memory device 123. However, a method of supplying the program to the computer is not limited to using the external memory device 123. For example, a communication line such as the Internet or an exclusive line may be used to supply the program without using the external memory device 123. Also, the memory device 500c or the external memory device 123 is configured as a non-transitory computer-readable recording medium. Hereinafter, these are collectively simply called a recording medium. When the term “recording medium” is used in this specification, it refers to either or both of the memory device 500c and the external memory device 123.

(2) Substrate Processing Process

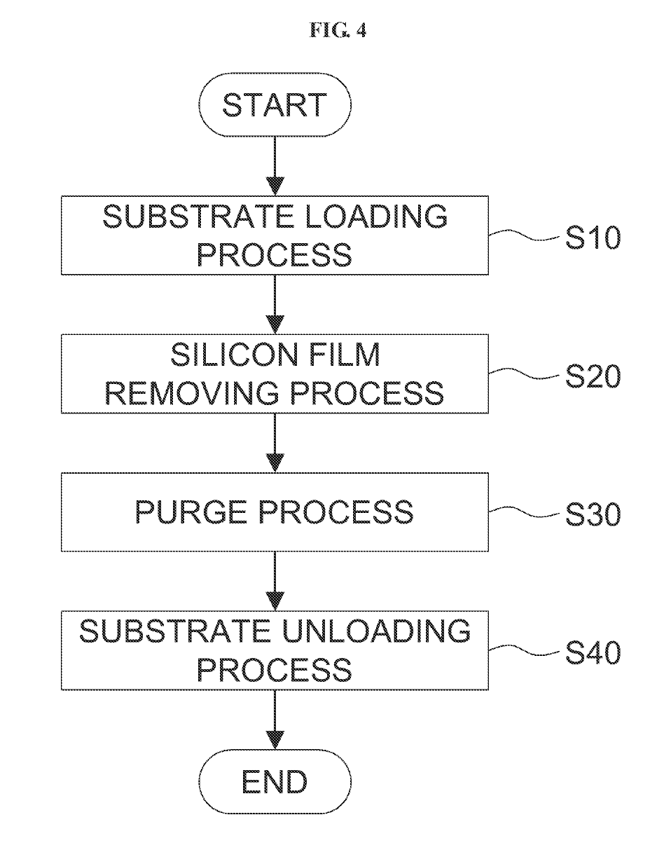

Next, the substrate processing process performed as a process among semiconductor manufacturing processes according to the present embodiment will be described with reference to FIG. 4. This process is performed by the above-described substrate processing apparatus. In the following description, operations of respective components of the substrate processing apparatus are controlled by the controller 500.

[Substrate Loading Process S10]

As illustrated in FIG. 2, first, the substrate 1 including a silicon-containing film is transferred by a substrate transfer robot from the substrate transfer chamber 40 to the substrate processing chamber 50 through the transfer port 8.

[Silicon Film Removing Process S20]

Next, the substrate support pin up and down mechanism 11 is lowered and the substrate 1 is placed on the susceptor 2. Here, lifting of the substrate support pin up and down mechanism 11 is performed by a lifting drive unit. The heater provided in the susceptor 2 is heated to a predetermined temperature in advance, and the substrate 1 is heated to about a room temperature to a low temperature, and a predetermined substrate temperature. As necessary, the cooling unit configured to discharge an excessive heat (reaction heat) is combined. Here, the term “low temperature” refers to a temperature range in which a removing gas or a processing gas to be described below is sufficiently vaporized and a temperature at which a characteristic of a film formed on the wafer (substrate) 1 is not modified. Then, only the susceptor 2 or the susceptor 2 and the substrate support pin up and down mechanism 11 are raised to the substrate processing position B, and the substrate 1 is placed on the susceptor 2.

Next, a predetermined processing gas is supplied to the substrate 1 from the shower head 5 through the gas supply pipes 6a and 6b, and etching of a silicon film from the substrate 1 is performed. An etching process of the silicon film is performed by supplying the removing gas to the substrate 1. As the etching gas serving as the processing gas, a halogen-containing gas is used. For example, a gas containing two or more halogen elements among fluorine (F), chlorine (Cl), bromine (Br) and iodine (I) is used. Preferably, a gas containing halogen elements of two types is used. Iodine pentafluoride (IF_{S}), bromine trifluoride (BrF₃), bromine pentafluoride (BrF₅), xenon difluoride (XeF₂) and chlorine trifluoride (ClF₃) are exemplified. More preferably, iodine heptafluoride (IF₇) is used. IF₇ can actively (selectively) remove the silicon-containing film. Here, the term “selectively” refers to, for example, setting an etching rate of the silicon-containing film to be higher than an etching rate of other films (for example, a metal film).

After the silicon film is etched, a purge process required to prepare for a next new process is preferably performed.

Also, when a modified layer of about several atomic layers is formed on the silicon film, the removing gas serving as a removing agent is preferably supplied to the substrate before the etching gas is supplied. Here, the term “modified layer” is an oxide film formed on the silicon film. This oxide film has a thickness of several atomic layers and is unable to be removed with the etching gas, and thus inhibits removal of the silicon film. When the removing gas is supplied, the modified layer can be removed while the silicon film or other film configurations are maintained, and the silicon film can be finely removed with the etching gas.

[Purge Process S30]

The etching gas used in the etching process is discharged through the exhaust port 7 that is installed at a side of the processing chamber 50 and communicates with the circular path 14. Next, the inert gas, for example, a nitrogen gas, is supplied to the substrate 1 from substantially the center part of the shower head 5 through an inert gas supply pipe 20. In this case, the nitrogen gas to be supplied is heated by a heating unit 23 and then supplied. Also, the supplied inert gas may be heated to a higher temperature than the etching gas. In this manner, when the inert gas is heated to a higher temperature than the etching gas, it is possible to increase efficiency of removing byproducts generated when etching is performed. Preferably, the inert gas supplied to the substrate processing chamber 50 may be heated to a sublimation temperature or more of either or both of byproducts and residues generated in the etching process and then supplied to the substrate. Therefore, it is possible to further increase efficiency of removing byproducts generated when etching is performed. More preferably, the inert gas is heated to a sublimation temperature or more of either or both of byproducts and residues generated in the etching process and is heated to a heat resistant temperature of a circuit formed on the substrate or a heat resistant temperature or less of an O ring installed near the substrate processing chamber 50.

When the etching gas is supplied, the APC valve adjusts an exhaust volume at the same time. Therefore, a pressure in the substrate processing chamber 50 remains at a predetermined pressure. The pressure remains at, for example, 0.1 Pa to 100 Pa. A flow rate of the etching gas is set to a predetermined flow rate in a range of about 0.1 slm to 10 slm, for example, 3 slm. Also, as necessary, an atmosphere of the substrate processing chamber 50 may be exhausted once and then a predetermined gas may be supplied. Also, when the etching gas is supplied, since etching of the silicon-containing film starts, it is preferable that the pressure or the gas flow rate be quickly set to the predetermined value.

When the required removing process is completed, supply of the processing gas is suspended and an atmosphere gas in a processing container 431 and a processing chamber 445 is exhausted. Also, the support pin 4 is raised, the substrate 1 is separated from the susceptor 2, and cooling is performed to a temperature at which transfer is possible.

[Substrate Unloading Process S40]

When cooling is performed to a temperature at which the substrate 1 can be transferred and the substrate is ready to be unloaded from the processing chamber, the substrate is unloaded in the reverse order of the substrate loading process S10.

(3) Structure of Susceptor

Here, a structure of the susceptor according to the present embodiment will be described in detail.

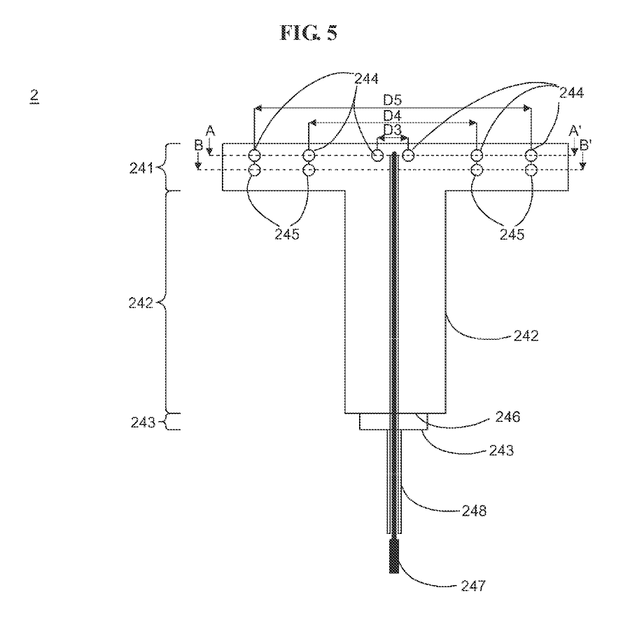

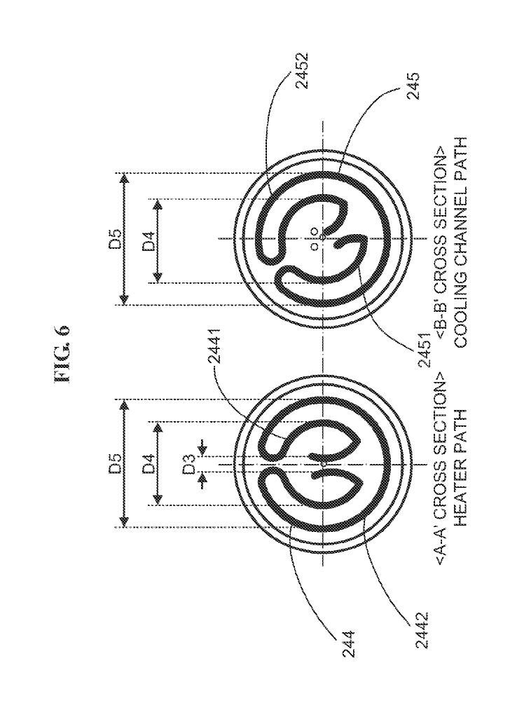

FIG. 5 is a cross sectional view of the wafer support 2 (hereinafter referred to as a “susceptor”) of the present embodiment. The susceptor 2 mainly includes a plate part 241 and a stem part 242, has a conventional form as an outline and may be deployed in various devices according to a redesign of an attachment part 243. A heater 244 serving as the heating device and a cooling channel 245 serving as the cooling device are disposed upward from the plate part 241. The heater 244 and the cooling channel 245 have a basic arrangement of an arcuate element, and are doubly or multiply wound. Reference examples of diameters include D3: φ 20 mm to φ 40 mm, D4: φ 130 mm to φ 170 mm and D5: φ 230 mm to φ 270 mm. In the present embodiment, a part indicated by a width D4 forms the inner circumferential part and a part indicated by a width D5 forms the outer circumferential part (refer to FIG. 6). That is, the heater 244 and the cooling channel 245 each include at least an inner circumferential part and an outer circumferential part. The inner circumferential part of the heater 244 is installed to vertically overlap the inner circumferential part of the cooling channel 245. The outer circumferential part of the heater 244 is installed to vertically overlap the outer circumferential part of the cooling channel 245. In such a configuration, it is possible to decrease a heat transmission loss from the heater to the cooling channel and easily perform temperature control.

A material of a main body of the susceptor 2 may include aluminum, stainless steel, a

Hastelloy and the like. An interface plate 246 is placed on a bottom surface of the stem part 242 and fastened to the attachment part 243 on a rear surface by fixing a bolt (not illustrated). As an object of the interface plate 246, for example, in order to provide a heating device (heater) terminal×2, a cooling device (cooling channel) terminal×2, and a thermal detector (T/C: thermocouple)×1, which is a temperature sensor (temperature detector), in a minimum space, O ring sealing of the cooling channel 245 whose sealing is necessary is integrally performed, and a T/C guide tube 248, which is an installation component configured to compress a thermal detector (T/C) 247 with a spring (not illustrated) at a rear surface, is disposed. Since the thermal detector 247 is fixed according to a constant force as described above, it has a structure in which a temperature change due to a change in an installation state according to heating and cooling is very small. Since the plate part 241 of the susceptor 2 needs to be integrally formed with the T/C guide tube 248, a material suitable for a welding process such as stainless steel or a Hastelloy is preferable.

As illustrated in the drawing, the thermal detector 247 has a leading end [a thermal detecting part of the thermal detector 247] that is disposed below a top surface of the susceptor 2 and above a lower end of the heater 244. Also, a heater power source 253 and a coolant supply unit 264 are controlled by the controller 500 such that, while a coolant is supplied to the cooling channel 245, when the wafer 1 is not placed on the susceptor 2, first power is supplied to the heater 244, and when the wafer 1 is placed on the susceptor 2, second power lower than the first power is supplied. In this manner, when the leading end of the thermal detector 247 is installed below the top surface of the substrate support 2 and above the lower end of the heater 244, it is possible to detect a change in the substrate temperature due to the reaction heat generated when the substrate process (etching process) is performed. Also, when the cooling channel 245 is installed (is isolated from the substrate) below the heater, it is possible to prevent supercooling of the substrate. Even if cooling is excessively performed, since the heater is provided at an upper side, the substrate can be heated. Also, when the substrate is placed on the susceptor and the substrate process is performed, if power supply to the heater 244 is set to be lower, it is possible to suppress temperature overshoot due to the reaction heat generated when the substrate is processed.

As another embodiment, the controller controls the heater power source 253 and the coolant supply unit 264 such that coolant supply to the cooling channel 245 is constantly maintained and a temperature of the susceptor 2 and the wafer 1 is changed according to power supply to the heater 244. When a processing temperature is in a low temperature range (for example, about 30° C. to 60° C.), an influence of an ambient temperature is easily delivered, and the temperature of the susceptor 2 or the wafer 1 is easily changed. However, according to performing such control, temperature adjustment of the low temperature range becomes easy.

FIG. 6 is a cross sectional view taken along A-A′ and B-B′ in FIG. 5. This explanatory diagram is a diagram illustrating a case in which each element is wound doubly, but it is similarly applied to a case in which each element is wound multiply, i.e., three or more times. The heater 244 and the cooling channel 245 have ends that are drawn from the stem part 242. In the heater 244 and the cooling channel 245, which are two terminals, with respect to an arrangement of the heater 244, the cooling channel 245 is arranged to rotate in a circumferential direction of the susceptor 2. Therefore, the terminals do not interfere with each other in the stem part 242. Also, as illustrated in FIG. 1 or 2, when an exhaust port 7 is disposed at an outer circumference of the plate part 241 of the susceptor 2, a gas is uniformly supplied to an end of the wafer 1. As described above, the heater 244 and the cooling channel 245 include at least inner circumferential parts 2441 and 2451 and outer circumferential parts 2442 and 2452. The inner circumferential part 2441 of the heater 244 is installed to vertically overlap the inner circumferential part 2451 of the cooling channel 245, and the outer circumferential part 2442 of the heater 244 is installed to vertically overlap the outer circumferential part 2452 of the cooling channel 245.

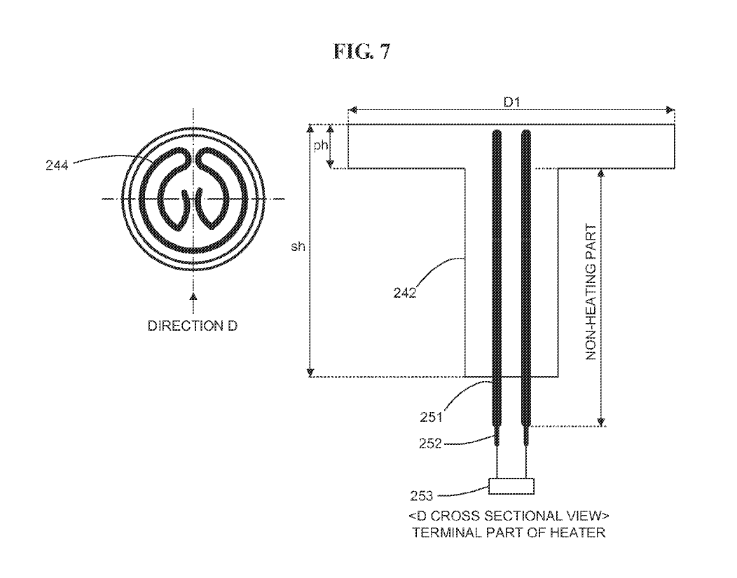

FIG. 7 illustrates a structure of a terminal part of the heater. When a heater of a sheath type and the like are embedded in the susceptor 2, since heat generation in the stem part 242 is unnecessary, a non-heating part is provided. Therefore, it is possible to remove unnecessary heat supply to the attachment part. The heater unit includes the heater 244, a sheath part 251, a rod part 252 and the heater power source 253. The sheath part 251 has a diameter of about φ 6 mm to φ 10 mm, and an output of 1.0 KW to 2.0 KW is assumed. Reference examples of each shape are as follows.

D1: φ 302 mm to φ 310 mm, ph: 40 mm to 60 mm, sh: 200 mm to 350 mm

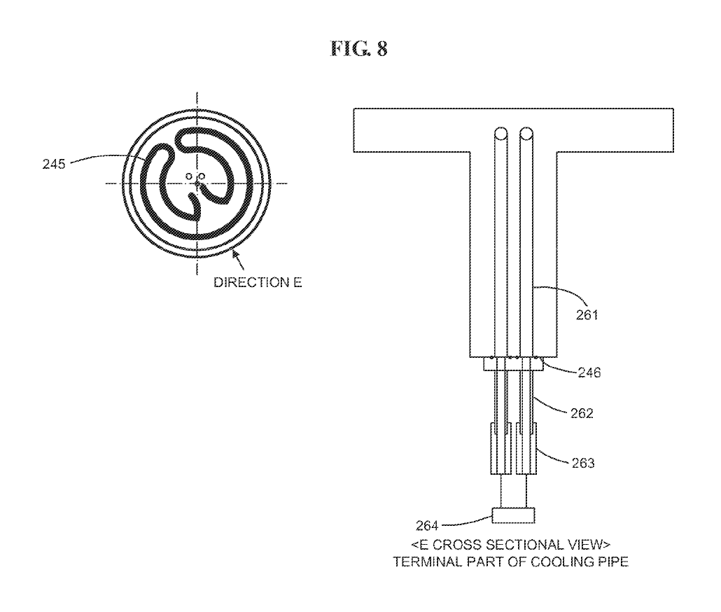

FIG. 8 illustrates a structure of a terminal part of a cooling pipe. This cooling unit mainly includes the cooling channel 245, a cooling pipe 261, the interface plate 246, a coupling 263 and the coolant supply unit 264. The cooling channel 245 may be configured such that a channel is formed in the susceptor 2 through a machining process or may have a structure in which a sheath made of a material such as stainless steel or a Hastelloy is interpolated, similarly to the heater. When the cooling channel is formed through the machining process, as illustrated in FIG. 8, it is necessary to seal a surface between the interface plate 246 and the stem part 242 by the O ring. Also, when the cooling channel is formed by interpolating the sheath, sealing in the interface plate 246 is unnecessary, and the sheath may be extracted to the outside through a through-hole installed at the interface plate 246. The channel has a diameter of about φ 6 mm to φ 10 mm (a flow rate of 1.0 slm to 5.0 slm). In the illustrated double wound arrangement, an effective channel length is about 1,000 mm to 2,000 mm, for example, Galden or Fluorinert may be used as the coolant to be introduced, and a heat transfer path that can establish heat exchange balance to be described below is ensured.

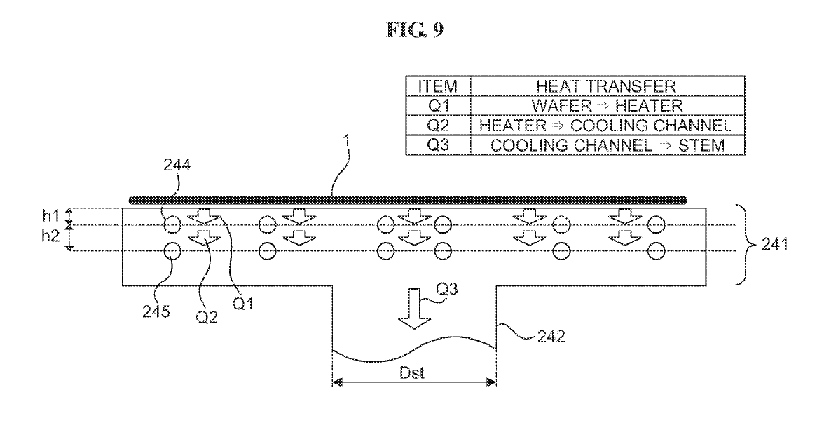

FIG. 9 is an image of a heat path according to the present embodiment. Q1 to Q3 indicate the following heat flows.

Q1: wafer [symbol] heater, Q2: heater [symbol] cooling channel, Q3: cooling channel [symbol] stem

The heater 244 is embedded at a depth of h1 from a susceptor surface, and the cooling channel 245 is embedded at a depth of h2 that is deeper than that of the heater 244. As an interpolation method of each element, for example, a lamination process by brazing, a machining process+an outer circumference EB welding (electron beam welding) process, a casting process or the like is appropriate. It is desirable that a dimension of h2 be calculated according to a diameter of each element and a minimum thickness of each element in the processing method. The heater 244 and the cooling channel 245 have a diameter of, for example, about φ 6 mm to φ 9 mm, and a dimension of h2 is about 9 mm to 19 mm. In the present embodiment, the heater 244 and the cooling channel 245 are installed to vertically overlap. Therefore, when a temperature of the heater 244 is controlled, it is possible to prevent a temperature of a part of the wafer 1 from locally decreasing due to the cooling channel 245. Also, since heat exchange between the heater 244 and the cooling channel 245 can be quickly performed, it is possible to decrease a temperature of the heater 244 or the wafer 1 with good responsiveness by decreasing power supply to the heater 244.

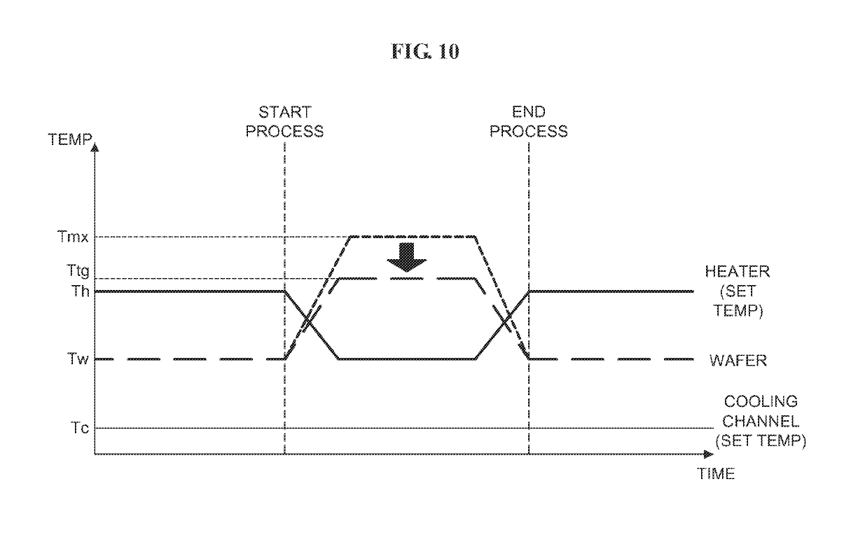

FIG. 10 shows the graph of an exemplary operation according to the present embodiment. A horizontal axis of the graph represents a time, and a vertical axis thereof represents a temperature of the wafer 1, the heater 244 and the cooling channel 245. An initial temperature Tw of the wafer 1 is assumed to be near a room temperature (about 20° C. to 25° C.). The susceptor 2 constantly introduces the coolant having a set temperature (Tc) (about 15° C. to 20° C.) to the cooling channel 245. The heater 244 is adjusted to a set temperature (Th) (about 40° C. to 50° C.). When no substrate process is performed, first power is supplied to the heater 244, and heat exchange between the heater 244 and the cooling channel 245 is mainly performed. After the substrate process starts, a temperature of the wafer 1 increases due to the reaction heat. The controller 500 performs monitoring and control such that an increase in a total amount of heat supply obtained from the heater 244 and wafer heat generation is suppressed, when the set temperature of the heater 244 is changed to be decreased as the wafer temperature increases, or when power supply from the heater power source 253 is decreased (for example, decreased to second power lower than the first power) and a heat generation amount from the heater 244 is decreased as the temperature detected by the thermal detector 247 increases. For example, it may be controlled such that a total amount of heat supply is the same as that of before the substrate process starts. Also, the controller 500 may monitor a detection temperature of the thermal detector 247 and control power supply from the heater power source 253 such that a temperature detected in the thermal detecting part of the thermal detector 247 becomes a predetermined temperature or less (for example, 50° C. to 60° C. or less). Also, the controller 500 may monitor a detection temperature of the thermal detector 247 and control power supply from the heater power source 253 such that a temperature of the wafer 1 becomes a predetermined temperature or less based on the temperature detected in the thermal detecting part of the thermal detector 247. When temperature control of the heater 244 is performed as described above, the wafer temperature after the temperature control becomes Ttg and the temperature of the wafer 1 may remain at a predetermined temperature or less (for example, 50° C. to 60° C. or less). Therefore, it is possible to suppress degradation of selectivity in silicon etching due to an increase in the temperature of the wafer 1, and stably perform the substrate process. When a susceptor having a structure other than the structure of the present embodiment is used to perform the substrate process, the wafer temperature increases to Tmx (for example, 60° C. to 80° C.) without absorbing the reaction heat (1000 W or less). Therefore, selectivity in silicon etching is degraded, or the wafer 1 has a low temperature (less than 20° C.) due to powerful cooling, and the processing gas is liquefied or solidified. Also, there is a concern about trouble such as condensation occurrence after the substrate is unloaded from the processing chamber. Also, residues of impurities added to silicon, residues in a pattern on the wafer or other byproducts are not removed and may be attached to the wafer. When temperature control in the present embodiment is performed, the wafer may have a temperature in a temperature range in which the substrate process such as silicon etching is appropriately performed. Also, in the present embodiment, particularly, since the temperature of the wafer 1 is controlled by setting a flow rate of the coolant supplied to the cooling channel 245 to be constant and controlling a temperature of the heater 244, control of the wafer temperature becomes easier, compared to when the coolant supply unit 264 is controlled.

The wafer 1 has a thickness of about 0.8 mm. In order to prevent a rear surface of the wafer 1 from being in direct contact with a metal of a top surface of the susceptor 2, a float pin (not illustrated) made of a material such as ceramics or quartz is installed on the top surface of the susceptor 2. The wafer 1 is placed on the float pin. The float pin has a height of about 0.1 mm to 0.3 mm.

(4) Effects According to the Present Embodiment

According to the present embodiment, one or a plurality of effects to be described below will be obtained.

(a) According to the present embodiment, in a process in which the wafer is heated and in a temperature range of about 30° C. to 70° C. in which an influence such as an ambient temperature is easily delivered and control thereof is difficult, it is possible to increase controllability of the wafer temperature and sensitively control the temperature.

(b) Also, according to the present embodiment, in process performance, it is possible to increase selectivity of silicon in silicon etching, set a temperature of the wafer to a temperature range in which added residues can decrease, and thus it is possible to increase performance of silicon etching. In particular, when IF₇ is used as the etching gas, a significant effect can be obtained in the present embodiment.

(c) Also, in terms of economy and efficiency, compared to a conventional structure in which heating and cooling are performed by separate components, the present embodiment can provide a method of exchanging heat with significantly higher efficiency.

### Other Embodiments of the Present Invention

The embodiments of the present invention have been described in detail above. However, the present invention is not limited to the above-described embodiments, but may be variously changed without departing from the scope of the invention.

The present invention may also applied to a liquid crystal display (LCD) manufacturing device configured to process a glass substrate, a substrate processing apparatus such as a solar cell manufacturing device and a micro electro mechanical systems (MEMS) manufacturing device, in addition to a semiconductor manufacturing device configured to process a semiconductor wafer such as the substrate processing apparatus according to the present embodiment.

According to the technology of the present invention, it is possible to absorb a reaction heat generated due to a substrate process in a low temperature range and keep a temperature of a susceptor at a predetermined temperature or less.

### Preferred Embodiments of the Present Invention

Hereinafter, preferred embodiments according to the present invention are supplementarily noted.

<Supplementary Note 1>

According to an aspect of the present invention, there is provided a substrate processing apparatus including:

a substrate support including a heater and a cooling channel;

a heater power supply configured to supply power to the heater;

a thermal detector including a thermal detecting part disposed lower than an upper surface of the substrate support and higher than lower ends of the heater and the cooling channel;

a coolant supply unit configured to supply a coolant to the cooling channel;

a controller configured to control the heater power supply and the coolant supply unit to: supply a first power to the heater without a substrate placed on the substrate support while supplying the coolant to the cooling channel; and supply a second power to the heater with the substrate placed on the substrate support while supplying the coolant to the cooling channel.

<Supplementary Note 2>

In the substrate processing apparatus of Supplementary note 1, preferably, the cooling channel is installed under the heater.

<Supplementary Note 3>

In the substrate processing apparatus of any one of Supplementary notes 1 and 2, preferably, the cooling channel is installed to vertically overlap the heater.

<Supplementary Note 4>

In the substrate processing apparatus of any one of Supplementary notes 1 and 2, preferably, the heater and the cooling channel includes an inner peripheral portion and an outer peripheral portion, respectively, the inner peripheral portion of the heater is installed to vertically overlap the inner peripheral portion of the cooling channel, and the outer peripheral portion of the heater is installed to vertically overlap the outer peripheral portion of the cooling channel.

<Supplementary Note 5>

In the substrate processing apparatus of any one of Supplementary notes 1 through 4, preferably, the controller is further configured to control the heater power supply and the coolant supply unit to constantly supply the coolant to the cooling channel and to change a temperature of the substrate by changing an amount of power supplied to the heater

<Supplementary Note 6>

In the substrate processing apparatus of any one of Supplementary notes 1 through 5, preferably, the controller is further configured to control the heater power supply and the coolant supply unit to maintain the second power to be less than the first power.

<Supplementary Note 7>

In the substrate processing apparatus of any one of Supplementary notes 1 through 6, preferably, the controller is further configured to control the coolant supply unit to constantly supply the coolant to the cooling channel.

<Supplementary Note 8>

In the substrate processing apparatus of any one of Supplementary notes 1 through 7, preferably, further includes a gas supply unit configured to supply a processing gas to the substrate, and the controller is further configured to control the gas supply unit to supply the processing gas to the substrate when the substrate is processed.

<Supplementary Note 9>

In the substrate processing apparatus of any one of Supplementary notes 6 through 8, preferably, the controller is further configured to control the heater power supply to adjust the second power based on a temperature detected by the heat detector such that a temperature of the substrate is equal to or lower than a predetermined value.

<Supplementary Note 10>

In the substrate processing apparatus of any one of Supplementary notes 8 and 9, preferably, the gas supply unit is further configured to supply an etching gas including two or more types of halogen elements.

<Supplementary Note 11>

According to another aspect of the present invention, there is provided a method of manufacturing a semiconductor device including:

(a) supplying a first power to a heater while supplying a coolant to a cooling channel without a substrate placed on a substrate support including the heater and the cooling channel where a thermal detector including a thermal detecting part disposed lower than an upper surface of the substrate support and higher than lower ends of the heater and the cooling channel is installed;

(b) placing the substrate on the substrate support; and

(c) supplying a second power to the heater while supplying the coolant to the cooling channel with the substrate placed on the substrate support.

<Supplementary Note 12>

In the method of Supplementary note 11, preferably, the cooling channel is installed under the heater.

<Supplementary Note 13>

In the method of any one of Supplementary notes 11 and 12, preferably, further includes constantly supplying the coolant to the cooling channel and changing a temperature of the substrate by changing an amount of power supplied to the heater.

<Supplementary Note 14>

In the method of any one of Supplementary notes 11 through 13, preferably, the coolant is constantly supplied to the cooling channel and the second power is less than the first power.

<Supplementary Note 15>

In the method of any one of Supplementary notes 11 through 14, preferably, the second power is adjusted in (c) based on a temperature detected by the heat detector such that a temperature of the substrate is equal to or lower than a predetermined value.

<Supplementary Note 16>

In the method of any one of Supplementary notes 11 through 15, preferably, the substrate includes a silicon film on a surface thereof, and the method further includes supplying an etching gas capable of removing the silicon film to the substrate.

<Supplementary Note 17>

According to another aspect of the present invention, there is provided a non-transitory computer-readable recording medium storing a program causing a computer to perform:

(a) supplying a first power to a heater while supplying a coolant to a cooling channel without a substrate placed on a substrate support including the heater and the cooling channel where a thermal detector including a thermal detecting part disposed lower than an upper surface of the substrate support and higher than lower ends of the heater and the cooling channel is installed;

(b) placing the substrate on the substrate support; and

(c) supplying a second power to the heater while supplying the coolant to the cooling channel with the substrate placed on the substrate support.

<Supplementary Note 18>

In the non-transitory computer-readable recording medium of Supplementary note 17, preferably, the cooling channel is installed under the heater.

<Supplementary Note 19>

In the non-transitory computer-readable recording medium of any one of Supplementary notes 17 and 18, preferably, further includes constantly supplying the coolant to the cooling channel and changing a temperature of the substrate by changing an amount of power supplied to the heater.

<Supplementary Note 20>

In the non-transitory computer-readable recording medium of any one of Supplementary notes 17 through 20, preferably, the coolant is constantly supplied to the cooling channel and the second power is less than the first power.

What is claimed is:

1. A substrate processing apparatus comprising:
a substrate support including a heater and a cooling channel;
a heater power supply configured to supply power to the heater;
a thermal detector comprising a thermal detecting part disposed lower than an upper surface of the substrate support and higher than lower ends of the heater and the cooling channel;
a coolant supply unit configured to supply a coolant to the cooling channel; and
a controller configured to control the heater power supply and the coolant supply unit to: supply a first power to the heater without a substrate placed on the substrate support while supplying the coolant to the cooling channel; and supply a second power to the heater with the substrate placed on the substrate support while supplying the coolant to the cooling channel.

2. The substrate processing apparatus of claim 1, wherein the cooling channel is installed under the heater to vertically overlap the heater.

3. The substrate processing apparatus of claim 2, wherein the controller is further configured to control the heater power supply and the coolant supply unit to constantly supply the coolant to the cooling channel and maintain the second power to be less than the first power.

4. The substrate processing apparatus of claim 1, further comprising a gas supply unit configured to supply a processing gas to the substrate, wherein the controller is further configured to control the gas supply unit to supply the processing gas to the substrate when the substrate is processed.

5. The substrate processing apparatus of claim 1, wherein the controller is further configured to control the heater power supply to adjust the second power based on a temperature detected by the heat detector such that a temperature of the substrate is equal to or lower than a predetermined value.

6. The substrate processing apparatus of claim 4, wherein the gas supply unit is further configured to supply an etching gas including two or more types of halogen elements.

7. A method of manufacturing a semiconductor device, comprising:
(a) supplying a first power to a heater while supplying a coolant to a cooling channel without a substrate placed on a substrate support including the heater and the cooling channel where a thermal detector comprising a thermal detecting part disposed lower than an upper surface of the substrate support and higher than lower ends of the heater and the cooling channel is installed;
(b) placing the substrate on the substrate support; and
(c) supplying a second power to the heater while supplying the coolant to the cooling channel with the substrate placed on the substrate support.

8. The method of claim 7, wherein the cooling channel is installed under the heater to vertically overlap the heater.

9. The method of claim 7, wherein the coolant is constantly supplied to the cooling channel and the second power is less than the first power.

10. The method of claim 7, wherein the second power is adjusted in (c) based on a temperature detected by the heat detector such that a temperature of the substrate is equal to or lower than a predetermined value.

11. The method of claim 7, wherein the substrate comprises a silicon film on a surface thereof, and further comprising supplying an etching gas capable of removing the silicon film to the substrate.

12. A non-transitory computer-readable recording medium storing a program that causes a computer to perform:
(a) supplying a first power to a heater while supplying a coolant to a cooling channel without a substrate placed on a substrate support including the heater and the cooling channel where a thermal detector comprising a thermal detecting part disposed lower than an upper surface of the substrate support and higher than lower ends of the heater and the cooling channel is installed;
(b) placing the substrate on the substrate support; and
(c) supplying a second power to the heater while supplying the coolant to the cooling channel with the substrate placed on the substrate support.
